(19) United States
(12) Patent Application Publication
(10) Pub. No.: US 2024/0421116 A1
(43) Pub. Date: Dec. 19, 2024

(54) INTEGRATED CIRCUIT ASSEMBLIES HAVING LOW SURFACE ENERGY EPOXY BARRIERS AND METHOD FOR EPOXY RESIN CONTAINMENT ON A SUBSTRATE

(71) Applicant: ACULON, INC., San Diego, CA (US)

(72) Inventors: Donald Cunningham, Dallas, TX (US); ERIC L. BRUNER, LA JOLLA, CA (US); Eric L. Hanson, Carlsbad, CA (US); Andres Hanau, San Diego, CA (US); Gloria Zarate, Oceanside, CA (US)

(21) Appl. No.: 18/752,001

(22) Filed: Jun. 24, 2024

Related U.S. Application Data
(63) Continuation-in-part of application No. PCT/US22/54028, filed on Dec. 26, 2022.
(60) Provisional application No. 63/293,683, filed on Dec. 24, 2021.

(51) Int. Cl. H01L 23/00; H01L 21/56; H01L 23/29; H01L 23/31; H01L 25/16

(52) U.S. Cl. CPC H01L 24/32; H01L 21/56; H01L 23/296; H01L 23/3121; H01L 24/16; H01L 24/26; H01L 24/29; H01L 24/73; H01L 24/83; H01L 25/16; H01L 2224/16225; H01L 2224/26175; H01L 2224/2919; H01L 2224/32225; H01L 2224/73204; H01L 2224/83001; H01L 2224/83862; H01L 2924/19041; H01L 2924/19105

(57) ABSTRACT

Integrated circuit assemblies are provided comprising: (a) a carrier substrate; (b) an electronic circuit component attached to the carrier substrate; (c) an epoxy resin disposed between the electronic circuit component and the carrier substrate or encapsulating the electronic circuit component; and (d) an epoxy barrier applied to the carrier substrate and surrounding the electronic circuit component. The epoxy barrier comprises a polymer having a surface energy less than that of the epoxy resin. Also provided is a method for epoxy resin containment on a substrate comprising: (a) applying the epoxy barrier described above to the substrate around a perimeter within which the epoxy resin is to be applied; and (b) applying the epoxy resin within the perimeter.

### RELATED APPLICATIONS

The present application is a continuation in part of international patent application serial number PCT/US2022/054028 filed Dec. 26, 2022 and published Jun. 29, 2023 as publication number WO-2023/122354, which publication and application are incorporated herein by reference. International patent application serial number PCT/US2022/054028 claims priority to U.S. Provisional Patent Application Ser. No. 63/293,683, filed Dec. 24, 2021, titled “Integrated Circuit Assemblies Having Low Surface Energy Epoxy Barriers and Method for Epoxy Resin Containment on a Substrate” which is incorporated herein by reference.

### FIELD OF THE INVENTION

The present invention relates to integrated circuit assemblies demonstrating low epoxy contamination and methods for epoxy resin containment on a substrate.

### BACKGROUND OF THE INVENTION

In the fabrication of integrated circuit assemblies, individual components are often attached to a carrier substrate using solder bumps. The spaces between the solder bumps under the component may be filled with an “underfill”. In a conventional underfill process, an adhesive material such as an epoxy resin is applied between the carrier substrate and the component substrate. The adhesive material is typically dispensed in liquid form onto the carrier substrate. The adhesive material is then drawn by capillary action between the carrier substrate and the component substrate. The hardened adhesive material attaches the component to the carrier substrate and protects the solder bumps from cracking in the finished integrated circuit assembly. Epoxy resins may also be used to encapsulate the electronic components.

Typical epoxy resins used to encapsulate components and stabilize surface mount integrated circuit (IC) packages as underfill have very low viscosities and surface tension, allowing them to flow into very small gaps (usually on a micron scale) over long distances, such as several millimeters. These epoxy resins can consequently flow and spread onto neighboring components and electrical contacts, which is not desirable, especially for ground point contacts, connectors, sensors, displays, which cannot tolerate surface contamination. Some components and circuits are sensitive to stresses induced by unexpected epoxy contamination.

This problem has been conventionally solved by applying a barrier in the form of a thick (millimeter scale) epoxy dam. Such epoxy dams are formed by dispensing a high viscosity sealant in a bead around the perimeter of the IC package to prevent flow of the underfill onto surrounding components. The dams may be pre-printed on a substrate surface with large epoxy keep-outs and tolerances so as not to disturb the assembly process. The dams are typically tall, wide, and bulky because there is little or no repellency towards the underfill epoxy resin. The epoxy resin can readily flow over the top of the dam in certain circumstances. Pre-applied underfill barriers require a large board footprint and large epoxy keep-out zones as a result, wasting valuable substrate area. The relatively large board footprint is a significant detriment in space-limited systems like smartphones and wearables. The conventional dams must also be applied well before the attachment of components, during substrate fabrication. Overall, the implementation of conventional epoxy dam structures is a complicated process which adds cost and complexity to the total system.

Intel Corporations U.S. Pat. Nos. 7,875,503 and 8,362,627 discloses methods for fabricating electronic devices including providing a substrate with a die attach area, and forming a layer on the substrate outside of the die attach area. The layer may be formed from a fluoropolymer material. The method also includes coupling a die to the substrate in the die attach area, wherein a gap remains between the die and the die attach area. The method also includes placing an underfill material in the gap and adjacent to the layer on the substrate. Examples of fluoropolymer materials which may be used include polytetrafluoroethylene (PTFE) and perfluoroalkoxy polymer resin (PFA).

Intel Corporations U.S. Pat. No. 11,282,717 discloses a substrate protrusion which includes a top portion that extends in a first direction toward a gap between the first die and the second die and in a second direction parallel to the gap between the first die and the second die. The substrate protrusion also includes a base portion that is coupled to a substrate that extends underneath the first die and the second die. The substrate protrusion can enable void-free underfill.

KAIST's (Korea Advanced Institute of Science and Technology) U.S. patent Publication 2015-0311177 discloses a chip packaging method using a hydrophobic surface includes forming superhydrophobic surfaces forming hydrophilic surfaces on predetermined positions of the superhydrophobic surfaces formed on the one of a first chip or the first board and the one of a second chip or a second board, respectively, generating liquid metal balls on the hydrophilic surfaces formed on the one of the first chip or the first board and the one of the second chip or the second board, respectively, and packaging the one of the first chip or the first board and the one of the second chip or the second board by combing the liquid metal ball of the one of the first chip or the first board and the liquid metal ball of the one of the second chip or the second board with each other.

Taiwan Semiconductor Manufacturing Co Ltd's (TSMC) U.S. patent Publication 2019-0139817 discloses a method and structure for packaging a semiconductor device are provided. In an embodiment a first substrate is bonded to a second substrate, which is bonded to a third substrate. A thermal interface material is placed on the second substrate prior to application of an underfill material. A ring can be placed on the thermal interface material, and an underfill material is dispensed between the second substrate and the third substrate. By placing the thermal interface material and ring prior to the underfill material, the underfill material cannot interfere with the interface between the thermal interface material and the second substrate, and the thermal interface material and ring can act as a physical barrier to the underfill material, thereby preventing overflow.

It would be desirable to provide an improved method for epoxy resin containment on a substrate and integrated circuit assemblies having effective epoxy barriers, which overcome the drawbacks of the prior art.

### SUMMARY OF THE INVENTION

Integrated circuit assemblies are provided comprising: (a) a carrier substrate; (b) an electronic circuit component attached to the carrier substrate; (c) an epoxy resin disposed between the electronic circuit component and the carrier substrate and/or encapsulating the electronic circuit component; and (d) an epoxy barrier applied to the carrier substrate and surrounding the electronic circuit component. The epoxy barrier comprises a polymer having a surface energy less than that of the epoxy resin.

The invention also provides a method for epoxy resin containment on a substrate comprising the steps of: (a) applying the epoxy barrier described above to the substrate around a perimeter within which the epoxy resin is to be applied; and (b) applying the epoxy resin within the perimeter. The high repellency of the epoxy barrier “directs” the epoxy to the intended location.

These and other advantages of the present invention will be clarified in connection with the following detailed description of the invention taken in connection with the associated figures.

### BRIEF DESCRIPTION OF THE DRAWINGS

FIGS. 1A and 1B are schematic cross-sectional views of a portion of an integrated circuit assembly according to respective aspects of the invention.

FIG. 2 is a schematic cross-sectional view of a portion of an integrated circuit assembly according to another aspect of the invention.

FIG. 3 is a schematic top view of the portion of an integrated circuit assembly shown in FIG. 2.

FIG. 4 is a schematic cross-sectional view of a comparison between a conventional integrated circuit assembly and an integrated circuit assembly of according to another aspect of the present invention, demonstrating an advantage of space savings on the substrate surface provided by the present invention.

### DETAILED DESCRIPTION OF THE INVENTION

Other than in any operating examples, or where otherwise indicated, all numbers expressing quantities of ingredients, reaction conditions and so forth used in the specification and claims are to be understood as being modified in all instances by the term “about.” Accordingly, unless indicated to the contrary, the numerical parameters set forth in the following specification and attached claims are approximations that may vary depending upon the desired properties to be obtained by the present invention. At the very least, and not as an attempt to limit the application of the doctrine of equivalents to the scope of the claims, each numerical parameter should at least be construed in light of the number of reported significant digits and by applying ordinary rounding techniques.

Notwithstanding that the numerical ranges and parameters setting forth the broad scope of the invention are approximations, the numerical values set forth in the specific examples are reported as precisely as possible. Any numerical value, however, inherently contain certain errors necessarily resulting from the standard deviation found in their respective testing measurements.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

As used in this specification and the appended claims, the articles “a,” “an,” and “the” include plural referents unless expressly and unequivocally limited to one referent.

The term “curable”, as used for example in connection with a curable composition, means that the indicated composition is polymerizable or cross linkable through functional groups, e.g., by means that include, but are not limited to, irradiation, thermal (including ambient cure) and/or catalytic exposure.

The term “cure”, “cured” or similar terms, as used in connection with a cured or curable composition, e.g., a “cured composition” of some specific description, means that at least a portion of the polymerizable and/or cross-linkable components that form the curable composition is polymerized and/or crosslinked. Additionally, curing of a polymerizable composition refers to subjecting said composition to curing conditions such as but not limited to thermal curing, leading to the reaction of the reactive functional groups of the composition, and resulting in polymerization and formation of a polymerizate. When a polymerizable composition is subjected to curing conditions, following polymerization and after reaction of most of the reactive end groups occurs, the rate of reaction of the remaining unreacted reactive end groups becomes progressively slower. The polymerizable composition can be subjected to curing conditions until it is at least partially cured. The term “at least partially cured” means subjecting the polymerizable composition to curing conditions, wherein reaction of at least a portion of the reactive groups of the composition occurs, to form a polymerizate. The polymerizable composition can also be subjected to curing conditions such that a substantially complete cure is attained and wherein further curing results in no significant further improvement in polymer properties, such as hardness.

The various aspects and examples of the present invention as presented herein are each understood to be non-limiting with respect to the scope of the invention.

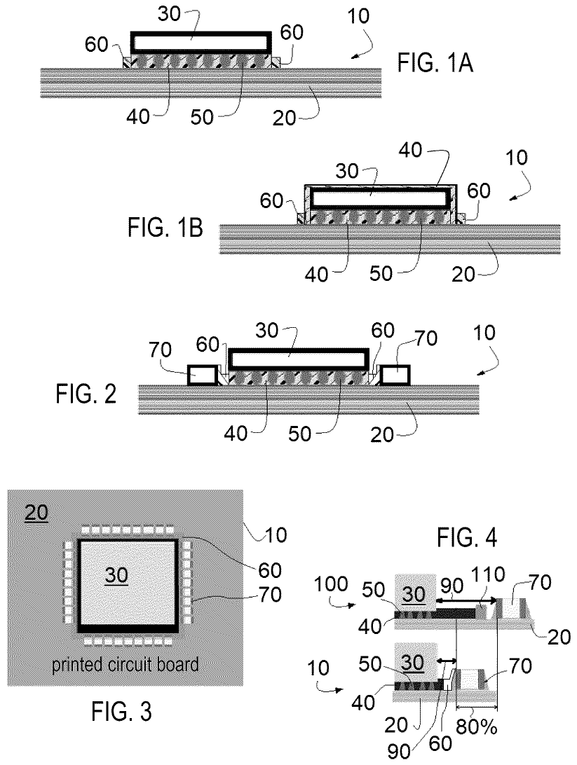

The present invention provides integrated circuit (IC) assemblies 10 such as semiconductor packages and printed circuit boards. An exemplary schematic representation is shown in FIG. 1A and an alternative is shown in FIGS. 1B, 2 and 3. FIG. 4 is a schematic cross-sectional view of a comparison between a conventional integrated circuit assembly 100 and an integrated circuit assembly 10 according to another aspect of the present invention, demonstrating an advantage of space savings on the substrate 20 surface provided by the present invention.

The assemblies 10 comprise (a) a carrier substrate 20. Substrates 20 suitable for use in the preparation of the integrated circuit assemblies 10 of the present invention can include a metal such as copper or steel, or any substrate 20 commonly used in the preparation of circuit assemblies, such as polyepoxides, including fiberglass reinforced polyepoxides, polyimides, phenolics, and fluorocarbons.

The assemblies 10 of the present invention further comprise (b) an electronic circuit component 30 attached to the carrier substrate 20 via solder elements 50 also known as solder bumps or solder balls. Examples of suitable components 30 include flip-chips, resistors, transistors, capacitors, and the like. The component 30 may be attached to the carrier substrate 20 using techniques known in the art. For example, the component 30 may be a surface mounted device (SMD), attached to the substrate 20 with solder balls or bumps 50 as shown in FIGS. 1A, 1B and 2. In another example as shown in FIG. 2, components 70 such as decoupling capacitors may be included.

The assemblies 10 of the present invention further comprise (c) an epoxy resin 40 that may be disposed between the component 30 and the carrier substrate 20, such as to fill voids between the solder bumps 50 of an SMD type component 30. Additionally or alternatively, the epoxy resin 40 may encapsulate the component 30 (shown in FIG. 1B) for insulating and protective purposes. Any epoxy resins known in the art for these purposes may be used.

The assemblies 10 of the present invention additionally comprise (d) an epoxy barrier 60 applied to the carrier substrate 20. The epoxy barrier 60 typically surrounds the component 30, applied to the substrate 20 around at least a portion of the perimeter or on any side of the component 30. The epoxy barrier 60 may additionally or alternatively be applied to the component 30 as a coating.

The epoxy barrier 60 comprises a polymer having a surface energy less than that of the epoxy resin 40. Since the surface tension of epoxy resins 40 is generally low (20-30 dyne/cm), it is important that the surface energy of the epoxy barrier 60 be below this range in order to properly repel the epoxy resin 40 and keep it from overflowing the barrier 60. Typically, the epoxy barriers 60 will have surface energies below 20 dyne/cm, and often less than 15 dyne/cm.

The polymer forming the barrier 60 is usually a fluorine-containing polymer (“fluoropolymer”) and may, for example, comprise perfluoroalkyl, perfluoroalkylsiloxane, perfluoroalkylether, and/or perfluoroaryl functional groups. Note that the phrase “and/or” when used in a list is meant to encompass alternative embodiments including each individual component in the list as well as any combination of components. For example, the list “A, B, and/or C” is meant to encompass seven separate embodiments that include A, or B, or C, or A+B, or A+C, or B+C, or A+B+C. Examples of such polymers include PTFE, TEFLON® AF, perfluorinated (meth)acrylic and (meth)acrylamide polymers, and perfluorinated poly(ether) polymers.

Suitable perfluorinated epoxy barriers 60 can also be formulated from discrete perfluorinated compounds that react to form a high molecular weight polymer, such as a mixture of isocyanate- and hydroxyl-functional compounds that are sufficiently perfluorinated to achieve repellency. Other examples include a siloxane polymer that has perfluorinated functional groups attached to the silicon atoms in the polymer backbone. One or more of such polymers may be used together.

The fluoropolymer forming the barrier 60 may, for example, be prepared by polymerizing one or more fluorinated ethylenically unsaturated monomers such as a fluoroethylene or fluoropropylene and fluoro-functional ethylenically unsaturated ester monomers such as fluoro-functional (meth)acrylate monomers and 2-Methyl-2-propenoic acid tridecafluorooctyl ester, with or without non-fluoro-functional ethylenically unsaturated monomers, using conventional polymerization techniques.

Other polymers that are suitable for use as the fluorinated polymer forming the barrier 60 include copolymers, such as terpolymers, of vinylidene fluoride, hexafluoropropylene, tetrafluoroethylene and/or perfluoromethylvinyl ether. The most suitable polymers for forming the barrier 60 are typically formed from perfluoroalkyl or perfluoroalkyl ether compounds, and contain reactive functional groups that allow for crosslinking such as isocyanate, active hydrogen, ethylenic unsaturation, etc., that may be cured thermally, by UV or other irradiation, or by free radical generation via peroxide or other initiator, as appropriate.

For some applications it may be desirable to control the molecular weight and polydispersity of the polymers used to form the barrier 60. These properties impact the rheological properties of these polymers as well as their resistance to dissolution/degradation by the epoxy resins 40. Controlled radical polymerization techniques such as atom-transfer radical polymerization (ATRP) and reverse addition fragmentation transfer (RAFT) can be used to prepare polymers with well controlled molecular weight distributions and polydispersity indices of <1.5.

Typically, the polymers forming the barrier 60 demonstrate an Mw value from 20-60 kD, often 25 to 35 kD, with a polydispersity around 1.3. Controlled molecular weight and polydispersity of the polymers allow for the prevention of such fabrication problems as clogging deposition equipment, film defects during deposition, and poor repellency or resistance to epoxy, etc.

The polymers forming the barrier 60 may be prepared as solutions for deposition onto the substrate surface as the epoxy barrier. For example, the polymer may be dissolved in one or more compatible solvents. Fluorinated solvents include perfluorodecalin, fluorinated alkanes with 8 to 18 carbons atoms, EnSolv NEXT solvents, available from Envirotech International. Inc.; VERTREL solvents available from E. I. DuPont de Nemours; GALDEN fluoroethers available from Solvay; and FLUORINERT, NOVEC, HFE-6512, HFE-7500 (2-(Trifluoromethyl)-3-ethoxydodecafluorohexane), and HFE-7700 (2,3,3,4,4-pentafluorotetrahydro-5-methoxy-2,5-bis[1,2,2,2-tetrafluoro-1-(trifluoromethyl)ethyl]-Furan) fluorosolvents, all available from 3M. Often the polymer is present in the solution in an amount of 30 to 40 percent by weight, such as 35 to 38 percent by weight, based on the total weight of the solution. A solution viscosity around 500-600 cP at ambient temperature allows for convenient application.

The epoxy barrier 60 may be applied to the substrate 20 by one or more of a number of methods such as by jet application, spray application, or dispensing with a needle. The barrier 60 may be applied in a desired pattern using an appropriate mask.

The lower surface energy of the epoxy barrier 60 relative to the epoxy resin 40 allows for a dramatic reduction in the barrier height and width compared to conventional epoxy dams 110, into the micron scale. Conventional epoxy dams 110 are in the millimeter dimensions, whereas the epoxy barrier 60 in the integrated circuit assemblies 10 of the present invention may be applied in dimensions of, for example, about 200 microns wide and about 20 to about 30 microns tall. Due to the difference in surface energy, the epoxy resin 40 is repelled by the barrier 60 and stops at the interface between the carrier substrate 20 surface and the epoxy barrier 60, keeping the epoxy resin 40 confined within the borders of the epoxy barrier 60. In fact, the epoxy barrier 60 repels the epoxy resin 40 to such a degree that the epoxy barrier 60 can be of a significantly lower height than the epoxy resin 40, as schematically illustrated in FIGS. 1-2.

However, the epoxy barrier 60 may be constructed of the same height as the epoxy resin 40 as shown schematically in FIG. 4 or even taller, although it is not necessary for efficacy. As discussed in connection with FIG. 4, the epoxy barrier 60 reduces the size of the epoxy keep out zone 90 that would otherwise be larger within other type dams 110 as illustrated in FIG. 4.

As shown in FIG. 4, chips or surface mount components 70 that are to be mounted outside an epoxy keep-out area 90 can be moved closer, such as up to 80% closer to the epoxy keep-out area 90, compared to conventional IC assemblies 100 that use existing epoxy dams 110. Unlike epoxy dams 110 on conventional IC assemblies 100, the epoxy barrier 60 may be applied to the carrier substrate 20 in a proximity of about 200 to about 400 microns to the electronic circuit component 30.

In the embodiment shown in FIG. 4, the epoxy barrier 60 includes a sloped side or edge extending up the component 70. The figures are intended to demonstrate some of the wide varieties of configurations of the epoxy barrier 60. As noted the epoxy repelling aspects of the barrier 60 allow an epoxy barrier to be applied of significantly less height than the height of the epoxy resin 40, however an epoxy barrier that coats the side of an adjacent component 70 and is higher than the epoxy resin 40 is also convenient (providing added protection to the component 70). Further, different heights of the epoxy barrier 60 relative to the epoxy resin 40 are possible in the same assembly 10, such as a lower height for the barrier 60 in areas between adjacent components 70 in the illustrated embodiment, and the configuration shown in FIG. 4 along each component 70.

The IC assemblies 10 of the present invention offer several advantages over those of the prior art. Some electronic components 30, 70 benefit from being closer together to reduce circuitry parasitics, such as high-speed data rates (microprocessors) or high frequency RF components (RF transceivers). For components 30 that use epoxy underfill 40, reducing the underfill keep-out area 90 around the underfill 40 containing component 30 allows these distance-sensitive components 70 to be closer together in denser configurations, as noted above. Alternatively, an overall semiconductor package substrate area or printed circuit board area can be reduced, which reduces cost. For size-sensitive products like smartphones, area reduction helps reduce product size and weight. Smaller printed circuit boards 10 or smaller semiconductor packages can allow for increasing the smartphone battery size.

The present invention is further drawn to a method for epoxy resin 40 containment on a substrate 20 such as a carrier substrate 20 in an integrated circuit assembly 10, or in any other context where an epoxy resin 40 needs to be contained on a substrate 20 surface or article, to prevent contamination of or damage to other parts of the article such as a coating or a plastic component. The method comprises (a) applying an epoxy barrier 60 to the substrate 20 around a perimeter within which an epoxy resin 40 is to be applied; and (b) applying the epoxy resin 40 within the perimeter.

Substrates 20 suitable for use in the method of the present invention can include glass, metals, or plastics. Suitable glass substrates 20 include soda-lime-silica glass, such as soda-lime-silica slide glass sold from Fisher, or alumino-silicate glass such as GORILLA® glass from Corning Incorporated, or DRAGONTRAIL® glass from Asahi Glass Co., Ltd. Suitable metal substrates 20 include substrates made of, for example, copper, brass, stainless steel or other steel alloy, aluminum, or titanium. Suitable examples of plastic substrates 20 include polymers prepared from polyol(allyl carbonate) monomers, e.g., allyl diglycol carbonates such as diethylene glycol bis(allyl carbonate); polyurea-polyurethane (polyurea urethane) polymers, which are prepared, for example, by the reaction of a polyurethane prepolymer and a diamine curing agent, a composition for one such polymer being sold under the trademark TRIVEX® by PPG; polymers prepared from polyol(meth)acryloyl terminated carbonate monomer, diethylene glycol dimethacrylate monomers, ethoxylated phenol methacrylate monomers, diisopropenyl benzene monomers, ethoxylated trimethylol propane triacrylate monomers, ethylene glycol bismethacrylate monomers, poly(ethylene glycol) bismethacrylate monomers, or urethane acrylate monomers; poly(ethoxylated Bisphenol A dimethacrylate); poly(vinyl acetate); poly(vinyl alcohol); poly(vinyl chloride); poly(vinylidene chloride); polyethylene; polypropylene; polyurethanes; polythiourethanes; thermoplastic polycarbonates, such as the carbonate-linked resin derived from Bisphenol A and phosgene, one such material being sold under the trademark LEXAN®; polyesters, such as the material sold under the trademark MYLAR®; poly(ethylene terephthalate); polyvinyl butyral; poly(methyl methacrylate), such as the material sold under the trademark PLEXIGLAS®, and polymers prepared by reacting polyfunctional isocyanates with polythiols or polyepisulfide monomers, either homopolymerized or co- and/or terpolymerized with polythiols, polyisocyanates, polyisothiocyanates and optionally ethylenically unsaturated monomers or halogenated aromatic-containing vinyl monomers. Also suitable are copolymers of such monomers and blends of the described polymers and copolymers with other polymers, e. g., to form interpenetrating network products. The method of the present invention is particularly useful in the preparation of the IC assemblies 10 of the present invention, such that any of the carrier substrates 20 listed above are suitable.

The substrate 20 may take any shape as desired for the intended application, such as flat, curved, bowl-shaped, tubular, or freeform. For example, the substrate 20 may be in the form of a flat plate having two opposing surfaces, such as would be suitable for use in an electronic circuit assembly 10.

Prior to application of the epoxy barrier 60 or any electronic circuit components 30, 70 on an IC assembly 10, the substrate 20 may be cleaned such as by argon plasma treatment or with a solvent such as IONOX 13416 or CYBERSOLV 141-R, both available from Kyzen.

The epoxy barrier 60 comprises a polymer having a surface energy less than that of the epoxy resin 40. Both the epoxy barrier 60 polymer and the epoxy resin 40 may be any of those disclosed above with respect to the IC assemblies 10 of the present invention, prepared as described above.

In IC assembly 10 applications, the epoxy barrier 60 may be applied to the substrate 20 before or after individual circuit components 30, 70. Unlike in the fabrication of conventional IC assemblies 100 with epoxy dams 110, the epoxy barrier 60 is usually applied after placement of components 70 on the substrate 20, and may be applied after fabrication of the assembly 10 is completed, allowing for precise placement of the epoxy barrier 60 prior to application of the epoxy resin 40. For example, the epoxy barrier 60 may be applied around an electronic circuit component 30 attached to the carrier substrate 20, surrounding the component 30 and applied to the substrate 20 around the perimeter of the component 30. The epoxy barrier 60 may additionally be applied to the surfaces of the components 70 (or 30) as a protective barrier coating.

The epoxy barrier 60 may be applied to the substrate 20 by one or more of a number of methods such as by jet application, spray application, or dispensing with a needle. The barrier 60 may be applied in a desired pattern using an appropriate mask. In the context of an IC assembly 10, the epoxy barrier 60 may be applied to the carrier substrate 20 in a proximity of about 200 to about 400 microns to an electronic circuit component 30, 70. The epoxy barrier 60 may be applied as a conformal coating on electronic circuit components 30, 70. Conformal coating protects electronic circuit components 30, 70 from epoxy stress. Applying the barrier coating 60 between electronic circuit components 30, 70 prevents capillary action of the epoxy resin under and between the electronic circuit components 30, 70.

After application of the epoxy barrier 60, the epoxy resin 40 is applied within the defined perimeter; for example, between a component 30 and the carrier substrate 20 of an IC assembly 10 as an underfill, to fill voids between the solder bumps 50 of an SMD component 30. Additionally or alternatively, the epoxy resin 40 may encapsulate a component 30.

In certain examples of the method of the present invention, the epoxy resin 40 may be allowed to cure and harden by exposing to appropriate conditions known in the art (heating, etc.) The epoxy barrier 60 may subsequently be removed from the substrate 12 if desired, such as through the use of solvents. Preferred solvents are fluorinated solvents because they dissolve the barrier, but ketones and esters can be used with physical wiping. However, it is not necessary to remove the barrier 60 after the epoxy resin 40 is cured, even from an IC assembly 10; the epoxy barrier 60 polymer is low stress (i. e., low modulus) and therefore does not induce any significant amount of stress to components 30 or 70 or the board surface of the substrate 20 and it can remain on the final product without causing any issues.

In addition to the advantages mentioned above with respect to the IC assemblies 10 of the present invention, since the flow of epoxy resin 40 (such as underfill epoxy) is unpredictable, epoxy resin 40 in the prior art methods can unexpectedly flow to sensitive components of an article 100 such as connectors, displays, and stress sensitive components of an IC assembly. The method of the present invention allows for an easy fix to repel excessive epoxy resin 40 flow and protect sensitive components 70 from being unexpectedly contaminated. The method can be used in the fabrication of any electronic assembly 10, after the design is completed and in full production.

Whereas particular embodiments of this invention have been described above for purposes of illustration, it will be evident to those skilled in the art that numerous variations of the details of the present invention may be made without departing from the scope of the invention as defined in the appended claims.

What is claimed is:

1. An integrated circuit assembly comprising:
(a) a carrier substrate;
(b) an electronic circuit component attached to the carrier substrate;
(c) an epoxy resin encapsulating the electronic circuit component and disposed between the electronic circuit component and the carrier substrate; and
(d) an epoxy barrier applied to the carrier substrate and surrounding the electronic circuit component, wherein the epoxy barrier comprises a polymer having a surface energy less than that of the epoxy resin.

2. The integrated circuit assembly of claim 1 wherein the electronic circuit component is attached to the carrier substrate with solder bumps.

3. The integrated circuit assembly of claim 1 wherein the epoxy barrier is applied to the carrier substrate in a proximity of about 200 to about 400 microns to the electronic circuit component.

4. The integrated circuit assembly of claim 1, wherein the polymer comprises a fluorine-containing polymer.

5. The integrated circuit assembly of claim 4 wherein the fluorine-polymer comprises perfluoroalkyl, perfluoroalkylsiloxane, containing perfluoroalkylether, and/or perfluoroaryl functional groups.

6. The integrated circuit assembly of claim 4 wherein the fluorine-containing polymer has a polydispersity index less than 1.5.

7. The integrated circuit assembly of claim 1, wherein the epoxy barrier demonstrates a surface energy less than about 20 dyne/cm.

8. The integrated circuit assembly of claim 7, wherein the epoxy barrier demonstrates a surface energy less than 15 dyne/cm.

9. A method for epoxy resin containment on a substrate having at least one electronic circuit component attached to the carrier substrate, said method comprising:
(a) applying an epoxy barrier to the substrate around at least a portion of a perimeter within which an epoxy resin is to be applied, wherein the epoxy barrier formed a conformal coating on at least one side of at least one said electronic circuit component attached to the carrier substrate; and
(b) applying the epoxy resin within the perimeter, wherein the epoxy barrier comprises a polymer having a surface energy less than that of the epoxy resin.

10. The method of claim 9 wherein the epoxy barrier is applied to the substrate by jet application, spray application, or dispensing with a needle.

11. The method of claim 9 wherein the substrate comprises a carrier substrate in an integrated circuit assembly.

12. The method of claim 11 wherein the epoxy barrier is applied around an electronic circuit component attached to the carrier substrate.

13. The method of claim 12 wherein the electronic circuit component is surface mounted to the substrate with solder bumps.

14. The method of claim 13 wherein the epoxy resin is disposed between the electronic circuit component and the carrier substrate as underfill.

15. The method of claim 12 wherein the electronic circuit component is encapsulated by the epoxy resin.

16. The method of claim 12 wherein the epoxy barrier is applied to the carrier substrate in a proximity of about 200 to about 400 microns to the electronic circuit component.

17. The method of claim 9, wherein the polymer comprises a fluorine-containing polymer.

18. The method of claim 17 wherein the fluorine-containing polymer comprises perfluoroalkyl, perfluoroalkylsiloxane, perfluoroalkylether, and/or perfluoroaryl functional groups.

19. The method of claim 9, further comprising:
(c) allowing the epoxy resin to cure; and
(d) removing the epoxy barrier from the substrate.

20. An integrated circuit assembly formed according to the method of claim 19.
